(19) United States
(12) Patent Application Publication
(10) Pub. No.: US 2012/0156436 A1
(43) Pub. Date: Jun. 21, 2012

(54) COLOR CONVERSION LUMINESCENT SHEET AND FABRICATION METHOD FOR THE SAME

(75) Inventors: Jai Kyeong KIM, Seoul (KR); Dae Seok NA, Daegu (KR)

(73) Assignee: KOREA INSTITUTE OF SCIENCE AND TECHNOLOGY, Seoul (KR)

(21) Appl. No.: 13/277,577

(22) Filed: Oct. 20, 2011

(30) Foreign Application Priority Data
Dec. 15, 2010 (KR) 10-2010-0128621

(51) Int. Cl. G02F 1/00; B32B 7/02; B32B 5/16; B05D 3/12; B05D 5/12; B05D 5/06; B05D 3/02; B32B 27/06; C09K 11/00

(52) U.S. Cl. 428/172; 427/66

(57) ABSTRACT

A color conversion luminescent sheet and a method of preparing the same, the color conversion luminescent sheet including: an optical sheet having a plurality of protrusions and depressions on its lower surface; a conductive layer disposed on the upper surface of the optical sheet; a color conversion luminescent layer deposited on the upper surface of the conductive layer and comprising a mixture of nanofibers and nanobeads having a binder resin and a color conversion luminescent material; and a protective layer on the upper surface of the color conversion luminescent layer, the protective layer having a stacked structure including an organic polymer protective layer and an inorganic thin protective layer.

### CROSS-REFERENCE TO RELATED PATENT APPLICATION

This application claims the benefit of Korean Patent Application No. 10-2010-0128621, filed on Dec. 15, 2010, in the Korean Intellectual Property Office, the disclosure of which is incorporated herein in its entirety by reference.

### BACKGROUND OF THE INVENTION

1. Field of the Invention

The present invention relates to a color conversion luminescent sheet and a method of manufacturing the same, and more particularly, to a color conversion luminescent sheet that absorbs light emitted from a light source and converts the light into light having a different wavelength, thereby emitting colored light or white light, and a method of manufacturing the color conversion luminescent sheet.

The present invention is a result of the research undertaken in conjunction with the Korea Institute of Science and Technology (KIST), entitled “Nanomaterials Technology Development Act of the 21^{st} Century Frontier R&D Program”, a national R&D program, organized by the Korean Ministry of Education, Science, and Technology [Project ID No.: 2010K000345; Title of Project: High-efficiency Light-emitting Nanomaterials Technology; and Research Period: Apr. 1, 2010 to Mar. 31, 2011].

2. Description of the Related Art

Various kinds of lighting devices are used to generate light or illuminate objects. Currently available common lighting devices such as incandescent lamps, mercury lamps, and fluorescent lamps mostly generate light by converting electric energy to light energy. However, these light sources need to be frequently replaced with new ones due to their high power consumption and short lifespan.

With increasing environmental concerns, use of fluorescent lamps and mercury lamps, which contains carcinogenic mercury that is considered a threat to the environment, tends to be more restricted. Furthermore, due to the requirement of a large installation space, complicated installation methods, and color adjustment difficulties, and having both point- and line-light source characteristics, these light sources have limited applications.

To address these drawbacks of general lighting devices, a variety of alternative light sources have been developed. Typical examples of these alternatives include lighting devices using light-emitting diodes (LEDs) and/or organic light-emitting diodes (OLEDs). These light sources are harmless to the human body, have long lifespans, and are not subject to environmental regulations, and thus are applicable as various kinds of light sources, such as in a light crystal display (LCD) backlight and for room lighting.

However, the use of white LEDs and white OLEDs are very restricted because their manufacture is complicated and costly to manufacture. For LEDs, which are currently widely used, light guide plates (LGPs) are used to manufacture white surface light sources out of blue LEDs. However, due to the high costs and high heat generation during their operation, these LEDs are not suitable for use as true surface light sources. Likewise, although white OLEDs are drawing attention as a light source comfortable to human eyes since they are surface light sources and advantageously cover a wide region in terms of color coordinates, they also face challenges in terms of material development and lifespan.

In the manufacturing of conventional color conversion sheets, light emitters are uniformly dispersed and mixed in a solution by such means as ultrasonic dispersion, mechanical dispersion (using a stirrer, a homogenizer, and the like), and electrostatic dispersion (using a dispersant, a charge controller, a surfactant, and the like). However, these methods only allow temporary dispersion and mixing. Even in those cases where a stable dispersion and mixture are obtained, differences in density and surface energy and local evaporation of the solvent result in the formation of inhomogeneous layers especially when spin casting, screen printing, bar coating, or doctor blade method is used in making sheets, and this in turn leads to such issues hindering commercialization as severely inconsistence in luminance and color coordinates attributable to irregularities in local thickness of the final luminescent sheet. Furthermore, the formation of inhomogeneous layers made facile color adjustment based on compositional changes hard to come by due to the low reproducibility of the color coordinates in white and color light sources based on compositional changes. The luminescent sheet thus obtained has found to have limited applications because they have low thermal resistance and are highly deformable at high temperatures. In addition, the low efficiency of the color conversion material of the luminescent sheet is another concern because this may seriously lower its optical efficiency. Conventional luminescent sheets also suffer from poor applicability to components of electronic circuitry.

### SUMMARY OF THE INVENTION

The present invention provides a color conversion luminescent sheet capable of emitting color light or white light by converting the light emitted from a light source to another wavelength. The object of the present invention is to provide a color conversion luminescent sheet with satisfactory light diffusion, heat resistance, durability against brittle fracture and moisture resistance.

The present invention provides a method of manufacturing the color conversion luminescent sheet.

The present invention provides a light-emitting device including the color conversion luminescent sheet.

According to an aspect of the present invention, there is provided a color conversion luminescent sheet including: an optical sheet having a plurality of protrusions and depressions on its lower surface; a conductive layer disposed on the upper surface of the optical sheet; and a color conversion luminescent layer deposited on the upper surface of the conductive layer and comprising a mixture of nanofibers and nanobeads having a binder resin and a color conversion luminescent material.

According to another aspect of the present invention, there is provided a method of preparing a color conversion luminescent sheet, the method including: forming a conductive layer on one surface of an optical sheet having a plurality of protrusions and depressions on the other surface; forming a mixed layer of nanofibers and nanobeads by spinning a color conversion luminescent composition prepared by mixing a binder resin, a color conversion luminescent material, and a solvent onto the upper surface of the conductive layer; and thermally pressing the mixed layer of nanofibers and nanobeads to form a color conversion luminescent layer.

According to another aspect of the present invention, there is provided a luminescent device including the foregoing color conversion luminescent sheet.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view illustrating a color conversion luminescent sheet according to an exemplary embodiment of the present invention;

FIG. 2 is an image of the surface of a microlens according to an embodiment of the present invention;

FIG. 3 is a schematic view of an, electrospinner according to an embodiment of the present invention;

FIG. 4 is an image of the surface of a color conversion luminescent layer according to an embodiment of the present invention;

FIG. 5 is a graph of the emission spectrum of the color conversion luminescent sheet according to an embodiment of the present invention; and

FIG. 6 is a plot of the color coordinates of the color conversion luminescent according to an embodiment of the present invention.

### DETAILED DESCRIPTION OF THE INVENTION

The present invention will now be described more fully with reference to the accompanying drawings, in which exemplary embodiments of a color conversion luminescent sheet and a method of manufacturing the same according to the present invention are shown. The present invention may, however, be embodied in many different forms and should not be construed as being limited to the embodiments set forth herein; rather, these embodiments are provided so that this disclosure will be thorough and complete, and will fully convey the concept of the invention to those of ordinary skill in the art.

The principle behind the color conversion luminescent sheets according to embodiments of the present invention involves absorbing a portion of the light emitted from a light source and emitting light with a wavelength different from that of the light source while transmitting the rest of the light and emitting white light or a light of a desired color by color conversion.

As used therein, the term “color conversion luminescent sheet” refers to an emission layer that converts the wavelength of light emitted from a light source, maximizes luminescent efficiency and improves the uniformity of light.

Upon irradiation of the color conversion luminescent material of the inventive sheet the light coming out from the blue light exciting material assumes a wavelength in the blue region, the light coming out from the red exciting material assumes a wavelength in the red region, and the light coming out from the green exciting material assumes a wavelength in the green region, while unexcited light retains the original light from the light source through transmittance. By appropriately combining these lights having the different wavelengths and intensities, white light as well as light of different colors may be generated.

Hereinafter, color conversion luminescent sheets according to exemplary embodiments of the present invention will be described more fully with reference to the appended drawings.

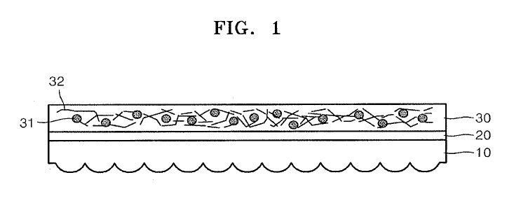

Referring to FIG. 1, a color conversion luminescent sheet according to an exemplary embodiment of the present invention includes an optical sheet 10 having a plurality of protrusions and depressions on its lower surface, a conductive layer 20 deposited on the upper surface of the optical sheet, and a color conversion luminescent layer 30 deposited on the upper surface of the conductive layer 20. The color conversion luminescent layer 30 includes nanobeads 31 and nanofibers 32.

Each of the protrusions and depressions of the optical sheet 10 may have a cross-section in a shape selected from among a triangular, a polygon, such as rectangles and hexagons, a semi-circular pillar a semi-oval pillar, a tetrahedron a cone, and a microlens.

The protrusions and depressions of the optical sheet 10 can be arranged in a honeycomb shape, a hexagonal shape, such as a non-cubic hexahedron, a diamond-like rhombic shape, a rectangular shape, or a triangular shape.

When the cross section has the form of a microlens, it may take the form of a plane-convex lens. To enable a control of a light-exit angle according to the direction in which light travels, the microlens may have a shape with different horizontal and vertical curvatures.

An array of microlenses on a surface of the optical sheet may have substantially zero spacing between themselves, i.e., a 100% fill-up ratio, to maximize the efficiency of light coming from the light source via the color conversion luminescent sheet. The cross-sectional shape of each of the microlenses may be spherical or non-spherical depending on the use of the color conversion luminescent sheet.

The light-exit angle of the microlens with respect to a direction perpendicular to the plane of the microlens may be about 30 degrees or greater left or right on the horizontal axis, and 10 degrees or greater up and down on the vertical axis. The term “light-exit angle” refers to an angle at which the half value of the front gain may be obtained.

The microlens may have a height of from about 2 μm to about 150 μm, and in some embodiments, may have a height of from about 3 μm to about 100 μm, and in some other embodiments, may have a height of from about 4 μm to about 80 μm. The microlens may have a radius of curvature of from about 2 μm to about 150 μm, and in some embodiments, may have a radius of curvature of from about 3 μm to about 100 μm, and in some other embodiments, may have a radius of curvature of from about 4 μm to about 80 μm.

When the height and the radius of curvature of the microlens are within these ranges, apparent transparency of the optical sheet may be improved, and the Moire phenomenon may not occur due to the reduction reduced light interference, further improving light transmittance.

A material for the optical sheet 10 may be any kind of polymer that allows the formation of protrusions and depressions and has a good light transmittance. Non-limiting examples of the material include polyethyleneterephthalate (PET), polymethylmethacrylate (PMMA), polycarbonate (PC), polyethylenenaphthalate (PEN), polystyrene (PS), and polyethylenesulfone (PES).

The optical sheet 10 may have a thickness of from about 100 μm to about 500 μm, and in some embodiments, may have a thickness of from about 120 μm to about 400 μm, and in some other embodiments, may have a thickness of from about 150 μm to about 300 μm. When the thickness of the optical sheet 10 is within these ranges, light transmission efficiency can be improved, and the optical sheet 10 may stably maintain its shape.

The conductive layer 20 may be formed by coating an inorganic conductive material, such as an inorganic oxide, or an organic conductive material, such as a conductive polymer, on the optical sheet 10. In some embodiments, the conductive layer 20 may include a conductive material selected from among indium tin oxide (ITO), F-doped SnO₂ (FTO), antimony tin oxide (ATO), indium zinc oxide (IZO), carbon nanotube, graphene, polypyrrole, polyaniline, and polythiophene.

The color conversion luminescent layer 33 disposed on the upper surface of the conductive layer 20 may include a binder resin, and a mixture of nanofibers and nanobeads including a color conversion luminescent material.

The color conversion luminescent layer 30 may be formed by spinning a color conversion luminescent composition that includes a binder resin, a color conversion luminescent material, and a solvent, on the upper surface of the conductive layer 20 to form a mixed nanofiber and nanobead layer, and thermally pressing the mixed nanofiber and nanobead layer.

The binder resin may include at least one selected from among polyurethane (PU), polyether urethane, polyurethane copolymer, cellulose acetate, cellulose acetate butyrate, cellulose acetate propionate, polymethyl acrylate (PMA), polymethyl methacrylate (PMMA), polyacrylic copolymers, polyvinyl acetate (PVAc), polyvinyl acetate copolymers, polyvinyl alcohol (PVA), polyfurfuryl alcohol (PPFA), polystyrene (PS), polystyrene copolymers, polyethylene oxide (PEO), polypropylene oxide (PPO), polyethylene oxide copolymers, polypropylene oxide copolymers, polycarbonate (PC), polyvinyl chloride (PVC), polycaprolactone (PCL), polyvinylpyrrolidone (PVP), polyvinylcarbazole (PVK), polyvinylidene fluoride (PVdF), polyvinylidene fluoride copolymers, and polyamide.

The color conversion luminescent material may include a material selected from among inorganic fluorescent materials, organic fluorescent materials, organic luminescent polymers, phosphorescent materials, quantum dots, and combinations thereof. The inorganic fluorescent materials may include any material emitting various wavelengths of light, including red, green, red, and orange wavelengths of light. Non-limiting examples of the inorganic fluorescent materials include metal oxides (YAG:Ce³⁺), silicates (Ca₃Sc₂Si₃O₁₂:Ce), metal sulfides, and metal nitrides. Non-limiting examples of the organic fluorescent materials include 4,4′-bis(2,2-diphenyl-ethene-1-yl)diphenyl (DPVBi), tris(8-quinolinato)aluminum(III) (Alq₃), and 4-dicyanomethylene-2-methyl-6-(julolidine-4-yl-vinyl-4H-phytane (DCM2). Non-limiting examples of the organic luminescent polymers include poly(4,4′-diphenylene diphenylvinylene (PDPV), poly p-phenylene (PPP), polyfluorene (PF), and polythiophene. Examples of the phosphorescent materials include metal complexes, such as PtOEP, Ir(PPy)₃, Ir(ThPy)₂acac, and Eu(TTFA)₃Phen, in which ions of elements such as platinum (Pt), tungsten (W), yttrium (Y), europium (Eu), and vanadium (V) are bound with an organic substance. Non-limiting examples of the quantum dots include composites, such as cadmium selenide (CdSe), cadmium sulfide (CdS), zinc selenide (ZnSe), zinc sulfide (ZnS), and zinc oxide (ZnO).

When at least two different color conversion luminescent materials are used, a composition ratio of the color conversion luminescent materials may be adjusted to obtain desired color coordinates. For example, when a blue luminescent polymer, green-wavelength quantum dots, and orange-wavelength quantum dots are used together as color conversion luminescent materials, the composition ratio of these materials may be from about 1:0.1:0.1 to about 1:10:10 by mass, and in some embodiments, may be from about 1:0.6:0.6 to about 1:5:5 by mass. When the mass ratios of these materials are within these ranges, the energy transfer from a larger-energy gap material to a smaller-energy gap material can be in a suitable range as to enable the control of color coordinates of the light generated.

The amount of the color conversion luminescent material may be from about 0.01 parts to about 20 parts by weight, and in some embodiments, may be from about 0.1 parts to about 15 parts by weight, and in some other embodiments, may be from about 0.5 parts to about 10 parts by weight, based on 100 parts by weight of the binder resin. When the amount of the color conversion luminescent material is within these ranges, light excitation and diffusion may be sufficient to increase the total luminance of the color conversion luminescent layer 30 and facilitate the control of energy transfer between the luminescent materials.

The color conversion luminescent layer 30 may have a thickness of from about 0.5 μm to about 200 μm, and in some embodiments, may have a thickness of from about 1 μm to about 150 μm, and in some other embodiments, may have a thickness of from about 10 μm to about 100 μm. When the thickness of the color conversion luminescent layer 30 is within these ranges, the color conversion luminescent layer may sufficiently absorb light emitted from the light source and incompletely transfer energy of the absorbed light, and thus, may vary the color coordinates.

A protective layer (not shown) may be further disposed on the upper surface of the color conversion luminescent layer 30. The protective layer may have a stacked structure including a substrate, an organic polymer protective layer and an inorganic thin protective layer. The protective layer may effectively block oxygen and moisture from entering the color conversion luminescent layer 30, ensuring stability and reliability of the color conversion luminescent sheet.

The substrate may be a plastic substrate or a glass substrate. Any appropriate plastic substrate commonly used for displays may be used. Non-limiting examples of the substrate include polymer films with strong resistance to heat and chemicals, including polyether sulfone, polycarbonate, polyethylene terephthalate, and polyimide films. Polyether sulfone films have good transparency. The substrate may have a thickness of about 100 μm to about 1,000 μm, and in some embodiments, may have a thickness of about 150 μm to about 500 μm. When the thickness of the substrate is within these ranges, a 90% or greater transparency requirement for use in displays may be ensured.

The organic polymer protective layer may include a cured light-curable polymer. Non-limiting examples of light-curable polymers include any ultraviolet (UV)-curable polymers, including epoxy resins, acrylic resins, polyimide resins, and polyethylene resins.

The organic polymer protective layer may have a thickness of about 0.1 μm to about 10 μm, and in some embodiments, may have a thickness of about 0.3 μm to about 7 μm, and in some other embodiments, may have a thickness of about 0.5 μm to about 5 μm. When the thickness of the organic polymer protective layer is within these ranges, the color conversion luminescent layer 30 may have a smoother surface, which may facilitate formation thereon of an inorganic thin protective layer that is able to block permeation of oxygen and moisture.

The inorganic thin protective layer may be formed by depositing at least two kinds of inorganic materials on the organic polymer protective layer. Examples of the inorganic materials include oxides, nitrides, and fluorides of metals and non-metals. In some embodiments, the inorganic thin protective layer may include at least two selected from among aluminum oxide, silicon oxide, silicon nitride, silicon oxynitride, magnesium oxide, indium oxide, and magnesium fluoride.

The ETL may have a thickness of about 150 Å to about 600 Å. When the thickness of the inorganic thin protective layer is within this range, the inorganic thin protective layer may block the permeation paths of moisture and oxygen that may occur due to defects such as pinholes, grain boundaries, and cracks in the organic polymer protective layer.

An adhesive layer may be further disposed on a lower surface of the substrate of the protective layer to facilitate attachment of the protective layer to an upper surface of the color conversion luminescent layer 30 of the color conversion luminescent sheet.

The adhesive layer may be formed of any appropriate resin that may exhibit adhesive characteristics even when in the presence of light, heat, moisture or oxygen, by using a method such as deposition. The adhesive layer may have a thickness of about 1 μm to about 5 cm, and in some embodiments, may have a thickness of about 1 μm to about 10 μm. When the thickness of the adhesive layer is within these ranges, the color conversion luminescent sheet may maintain the light transmission efficiency while supporting a durable attachment of the protective layer on the luminescent.

A protective layer may be further disposed between the optical sheet and the conductive layer. This is for blocking moisture and oxygen from entering not only the upper surface but also the lower surface of the color conversion luminescent layer through the conductive layer to improve stability of the color conversion luminescent sheet.

The color conversion luminescent sheet can ultimately be attached to a light source, for example, a luminescent device or a lamp comprising an organic light-emitting device (OLED) or an inorganic light-emitting device (LED) which emits ultraviolet (UV) light, blue light, or monochromatic light. An adhesive layer may be further deposited on the upper surface of the protective layer to facilitate attachment of the protective layer on the color conversion luminescent sheet to prevent deterioration due to moisture and oxygen.

According to another aspect of the present invention, a method of preparing a color conversion luminescent sheet is provided. This method includes the steps of: forming a conductive layer on one surface of an optical sheet having a plurality of protrusions and depressions on the other surface; forming a mixed layer of nanofibers and nanobeads by spinning a color conversion luminescent composition prepared by mixing a binder resin, a color conversion luminescent material, and a solvent, onto the upper surface of the conductive layer; and thermally pressing the mixed layer of nanofibers and nanobeads to form a color conversion luminescent layer.

The forming of the conductive layer may vary according to the kind of a conductive material for forming the conductive layer. When the conductive material includes an inorganic conductive material, such as indium tin oxide (ITO), F-doped SnO₂ (FTO), antimony tin oxide (ATO), indium zinc oxide (IZO), carbon nanotubes, or graphene, the conductive layer may be formed using electron beam deposition equipment, sputtering, physical vapor deposition (PVD), chemical vapor deposition (CVD), atomic layer deposition (ALD), or the like. When the conductive material includes an organic conductive material, such as polypyrrole, polyaniline, or polythiophene, the conductive layer may be formed using spin coating, screen printing, bar coating, an inkjet method, dipping, or the like.

Subsequently, the mixed layer of nanofibers and nanobeads is formed by spinning on the upper surface of the conductive layer, the color conversion luminescent composition, which is prepared by mixing the binder resin, the color conversion luminescent material and the solvent.

The binder resin may include at least one selected from the group consisting of polyurethane (PU), polyether urethane, polyurethane copolymer, cellulose acetate, cellulose acetate butyrate, cellulose acetate propionate, polymethyl acrylate (PMA), polymethyl methacrylate (PMMA), polyacryl copolymer, polyvinyl acetate (PVAc), polyvinylacetate copolymer, polyvinylalcohol (PVA), polyfurfuryl alcohol (PPFA), polystyrene (PS), polystyrene copolymers, polyethylene oxide (PEO), polypropylene oxide (PPO), polyethylene oxide copolymers, polypropylene oxide copolymers, polycarbonate (PC), polyvinyl chloride (PVC), polycaprolactone (PCL), polyvinylpyrrolidone (PVP), polyvinylcarbazole (PVK), polyvinylidene fluoride (PVdF), polyvinylidene fluoride copolymers, and polyamide.

The color conversion luminescent material may include a material selected from among inorganic fluorescent materials, organic fluorescent materials, organic luminescent polymers, phosphorescent materials, quantum dots, and combinations thereof. Non-limiting examples of the inorganic fluorescent materials include metal oxides (YAG:Ce³⁺), silicates (Ca₃Sc₂Si₃O₁₂:Ce), metal sulfides, and metal nitrides. Non-limiting examples of the organic fluorescent materials include 4,4′-bis(2,2-diphenyl-ethene-1-yl)diphenyl (DPVBi), tris(8-quinolinato)aluminum(III) (Alq₃), and 4-dicyanomethylene-2-methyl-6-(julolidine-4-yl-vinyl-4H-phytane (DCM2). Non-limiting examples of the organic luminescent polymers include poly(4,4′-diphenylene diphenylvinylene (PDPV), poly (p-phenylene) (PPP), polyfluorene (PF), and polythiophene. Examples of the phosphorescent materials include metal complexes, such as PtOEP, Ir(PPy)₃, Ir(ThPy)₂acac, and Eu(TTFA)₃Phen, in which ions of elements such as platinum (Pt), tungsten (W), yttrium (Y), europium (Eu), and vanadium (V) are bound with an organic substance. Non-limiting examples of the quantum dots include composites, such as cadmium selenide (CdSe), cadmium sulfide (CdS), zinc selenide (ZnSe), zinc sulfide (ZnS), and zinc oxide (ZnO).

The amount of the color conversion luminescent material may be from about 0.01 parts to about 20 parts by weight, and in some embodiments, may be from about 0.1 parts to about 20 parts by weights, and in some other embodiments, may be from about 0.5 parts to about 10 parts by weight, based on 100 parts by weight of the binder resin. When the amount of the color conversion luminescent material is within these ranges, light excitation and diffusion may be sufficient to increase the total luminance of the color conversion luminescent layer 30 and facilitate control of the energy transfer between the luminescent materials.

The solvent may include at least one selected from polar solvents, including water, acetone, ethanol, methanol, dimethylformamide (DMF), dimethylsulfoxide, ethylacetic acid, tetrahydrofuran (THF), dichloromethane, trifluoroethylene, and trichloroethylene, and nonpolar solvents, including benzene, toluene, xylene, hexane, chlorobenzene, dichlorobenzene, cyclohexane, chloroform, tetrachloroethylene (PCE), tetrachlorocarbon, and kerosene.

Advantageously, organic materials may find use as the color conversion luminescent material due to their high solubility in nonpolar solvents and their propensity to efficaciously form fibers in polar solvents upon spinning the color conversion luminescent composition.

Thus, in another embodiment of the present invention, the solvent may include both a polar solvent and a nonpolar solvent to take advantage of polar and nonpolar solvents.

A weight ratio of the polar solvent to the nonpolar solvent may be from about 2:98 to about 60:40, and in some embodiments, may be from about 5:95 to about 50:50, and in some other embodiments may be from about 10:90 to about 40:60.

When the weight ratio of the polar solvent to the nonpolar solvent is within these ranges, only spherical beads may be prevented from being spun off, but not fibers having a specific fibrous degree, due to an excess of the nonpolar solvent, and spinning of the color conversion luminescent composition itself may be prevented from being hindered due to an excess of the polar solvent that does not allow uniform dissolution of the color conversion luminescent material. As a result, the color conversion luminescent layer including mixed nanofibers and nanobeads may be obtained with an enhanced light scattering effect.

The amount of the solvent may be from about 200 parts to about 10,000 parts by weight based on 100 parts by weight of the binder resin, and in some embodiments, may be from about 300 parts to about 3,000 parts by weight, and in some other embodiments, may be from about 400 parts to about 2,000 parts by weight.

When the amount of the solvent is within these ranges, preparation of the color conversion luminescent composition may be facilitated, and a good fibrous form may be obtained.

The spinning may be carried out using, but is not limited to, electro-spinning, melt-blown spinning, electro-blown spinning, flash spinning, or electrostatic melt-blown spinning.

The conductive layer may have an area specific resistance of about 10 Ω/sq to about 2,000 Ω/sq, and in some embodiments, may have an area specific resistance of about 10 Ω/sq to about 1000 Ω/sq, and in some other embodiments, may have an area specific resistance of about 10 Ω/sq to about 500 Ω/sq. When the area specific resistance of the conductive layer is within these ranges, the color conversion luminescent layer may be formed to uniformly include nanofibers and nanobeads.

The nanofibers in the color conversion luminescent layer may have an average diameter of about 10 nm to about 10,000 nm, and in some embodiments, may have an average diameter of about 30 nm to about 4,000 nm, and in some other embodiments, may have an average diameter of about 50 nm to about 2,000 nm. The nanobeads in the color conversion luminescent layer 30 may have an average diameter of about 30 nm to about 10,000 nm, and in some embodiments, may have an average diameter of about 40 nm to about 4,000 nm, and in some other embodiments, may have an average diameter of about 50 nm to about 2,000 nm.

If the average diameters of the nanofibers and the nanobeads are so large that they contain a relatively large-diameter single luminescent material therein, the concentration of the luminescent material may be insufficient to attain desired luminescence. This may occur even when at least two different luminescent materials are contained in the nanofibers and nanobeads having a large average diameter, and furthermore, the luminescent materials may be too far away from each other, which may lead to hindered energy transfer therebetween, and thus are unlikely to enable color adjustment and luminescence improvement.

The thermal pressing may be performed at a temperature that is greater or equal to a glass transition temperature (Tg) and less or equal a melting point (Tm) of the binder resin. For example, the thermal pressing may be performed at a temperature of about 25° C. to about 150° C., and in some embodiments, may be performed at a temperature of about 30° C. to about 120° C., and in some other embodiments, may be performed at a temperature of about 40° C. to about 100° C. The thermal pressing may be performed for a duration of about 30 seconds to about 10 minutes, and in some embodiments, may be performed for a duration of about 1 minute to about 5 minutes. The pressure of the thermal pressing per 100 cm² may be from about 0.1 ton to about 20 tons, and in some embodiments, may be from about 1 ton to about 10 tons.

When the temperature, duration, and pressure of the thermal pressing are within these ranges, the thickness and porosity of the color conversion luminescent layer 30 may be appropriately controlled to sufficiently absorb and transmit light emerging from a light source, which may result in improved luminance and allow light having desired color coordinates to be emitted.

The method of preparing the cover conversion luminescent sheet may further include forming a protective layer on the upper surface of the color conversion luminescent layer.

The forming of the protective layer may include forming an organic polymer protective layer by coating the upper surface of a substrate with a photocurable polymer and curing the coated photocurable polymer, and forming an inorganic thin protective layer by depositing at least two different inorganic materials on an upper surface of the organic polymer protective layer.

After an adhesive layer is attached to the lower surface of the substrate, a protective layer may be formed on the upper surface of the color conversion luminescent layer with the adhesive layer therebetween.

The coating of the photocurable polymer may be performed using any appropriate method known in the art, for example, using spin coating, screen printing, bar coating, inkjet coating, or deep coating. In some embodiments, the photocurable polymer may be coated to cover an organic electronic device mounted on a substrate, or the front or both the front and rear surfaces of a plastic substrate, using a spin coater. For example, the light-curable polymer may be deposited to a thickness that is commonly applied in the art, and in some embodiments, may be deposited to a thickness of about 0.1 μm to about 10 μm.

Suitable examples of the light-curable polymer include, but are not limited to, UV-curable polymers, such as epoxy resins, acrylic resins, thermosetting polyimides, and polyethylene.

After being coated on the upper surface of the substrate, the photocurable polymer may be cured to form the organic polymer protective layer by irradiating short-wavelength UV and ozone (UV/O₃).

The UV/O₃ curing may involve preliminary curing, UV/O₃ irradiation, and thermal curing. In particular, while the coated photocurable polymer is preliminarily cured using a hot plate or an oven at a temperature of about 70° C. to about 90° C. for about 2 minutes to about 5 minutes, an additive or impurities contained in the light-curable polymer, for example, an acrylic resin, is slowly removed.

The photocurable polymer preliminarily cured is irradiated by UV/O₃ in a photocuring process. In the photocuring process involving the UV/O₃ irradiation, light having a wavelength of about 170 nm to about 200 nm is radiated to decompose oxygen molecules (O₂) into oxygen atoms, followed by radiating light having a wavelength of about 240 nm to about 260 nm for about 1 minute to about 7 minutes to generate ozone (O₃). The main wavelength of the light that directly affects the curing may range from about 240 nm to about 260 nm. The energy of the light irradiated may be from about from 2,400 mJ/cm² to about 3,000 mJ/cm². Finally, the photocurable polymer is thermally cured using an oven at a temperature of about 100° C. to about 120° C. for about 1 hour to about 2 hours to form the organic polymer protective layer. The above-described UV/O₃ curing process may lead to a greater degree of curing compared to a curing process using only UV, and may lead to greater interfacial adhesiveness, markedly enhancing the function of the protective layer.

In one embodiment of the UV/O₃ curing process, after preliminary curing is performed using a hot plate at a low temperature of about 80° C. for about 3 minutes, light having a wavelength of about 184.9 nm may be irradiated for about 5 minutes to decompose oxygen molecules (O₂) into oxygen atoms, which then may be exposed to irradiation of light having a wavelength about 253.7 nm for about 5 minutes to generate ozone (O₃) from the oxygen atoms. In this embodiment, the main wavelength of the light that directly affects the curing may be about 253.7 nm, and the energy of the light irradiated may be about 2800 mJ/cm². After the UV/O₃ curing is completed, thermal curing may be further performed using an oven at a temperature of about 120° C. for about 2 hours.

Next, the inorganic thin protective layer may be formed by depositing at least two different inorganic materials on the organic polymer protective layer formed as described above.

On the organic polymer protective layer formed on the upper surface of the color conversion luminescent layer by using the UV/O₃ curing process, a nanocomposite material including a mixture of at least two different inorganic materials is deposited using electron beam deposition equipment, sputtering, physical vapor deposition (PVD), chemical vapor deposition (CVD), or atomic layer deposition (ALD), to form the inorganic thin protective layer, thereby resulting in an organic/inorganic composite thin protective layer. The inorganic thin protective layer may have a thickness that is commonly applied in the art, and in some embodiments, may have a thickness of about 0.1 μm to about 0.5 μm.

The inorganic materials for forming the inorganic thin protective layer may be selected from among oxides, nitrides, fluorides of metals and non-metals. The inorganic thin protective layer may include at least two materials selected from among aluminum oxide, silicon oxide, silicon nitride, silicon oxynitride, magnesium oxide, indium oxide, and magnesium fluoride.

The inorganic thin protective layer may improve resistance to moisture and oxygen by blocking the permeation paths of moisture and oxygen that may be caused by defects such as pinholes, grain boundaries, and cracks in the organic polymer protective layer formed prior to the inorganic thin protective layer.

The organic polymer protective layer and the inorganic thin protective layer may be repeatedly formed to obtain a multi-layer stack of organic/inorganic composite thin protection layers including at least one pair of the organic polymer protective layer and the inorganic thin protective layer.

In some embodiments, prior to forming the organic polymer protective layer, the inorganic thin protective layer may be formed, and then the organic polymer protective layer may be formed thereon to obtain an inorganic/organic composite protective layer. Or one pair or more of the inorganic thin protective layer and the organic protective layer produced in this stack order, may be repeatedly deposited to form a multi-layer stack of inorganic/organic composite protective layers.

In other embodiments, in the organic/inorganic composite thin protective layer the stack order of the organic polymer protective layer and the inorganic thin protective layer may be reversed. One pair of the organic polymer protective layer and the inorganic thin protective layer may be repeatedly stacked to form a multi-layer stack. The organic/inorganic composite thin protective layer in either of these forms may effectively block the permeation of moisture and oxygen.

Methods of forming the organic/inorganic composite thin protective layer, according to embodiments of the present invention, provide the following advantages.

Firstly, the use of ultraviolet/ozone (UV/O₃) curing allows formation of the organic polymer protective layer capable of more effectively blocking moisture and oxygen compared to general UV curing methods. The UV/O₃ curing method enhances the surface energy of the organic polymer protective layer and induces it to be hydrophilic to improve the adhesiveness to the upper protective layer. The UV/O₃ curing method also enables formation of a full cover protective layer or repeated protective layers not only on the entire surface of an organic electronic device, but over a wider area, so that the permeation paths of moisture and oxygen into, for example, a large-sized organic luminescent device in a vertical direction and/or a horizontal direction may be effectively blocked, which improves stability and reliability of the device.

Secondly, the organic polymer protective layer is able to absorb extra moisture due to the surface thereof being hydrophilated due to the UV/O₃ curing method, thus suppressing damage of the device caused due to moisture.

Thirdly, the highly cross-linked structure of the organic polymer protective layer formed by the UVO₃ curing method can block the permeation paths of moisture and oxygen in a vertical direction, thus improving resistance to moisture and oxygen permeation.

Fourthly, by depositing a mixed inorganic protective layer including a nano composite mixture of at least two inorganic materials on the organic polymer protective layer prepared as described above, an organic/inorganic composite thin protective layer capable of effectively blocking permeation of moisture and oxygen may be formed.

The organic/inorganic composite thin protective layer may effectively block permeation of external oxygen and moisture, and thus may be used to ensure the luminescent device has improved stability and reliability, and the color conversion luminescent layer has improved gas-barrier characteristics.

In one embodiment, the method of preparing the color conversion luminescent sheet may further include, forming a protective layer on the upper surface of the optical sheet before the forming of the conductive layer.

As described above, this is for blocking moisture and oxygen from entering not only the upper surface but also the lower surface of the color conversion luminescent layer through the conductive layer to improve the stability of the color conversion luminescent sheet.

In one embodiment of the present invention, the method of preparing the color conversion luminescent sheet may further include forming an adhesive layer on an upper surface of the protective layer. The adhesive layer may be formed of any appropriate resin that may exhibit adhesion upon exposure to light, heat, moisture or oxygen. Exemplary resins include, for example, acrylate resins, silicon resins, or epoxy resins, by using a method that is commonly used in the art, such as spin coating, screen printing, bar coating, an inkjet method, or a dipping method.

According to another exemplary embodiment of the present invention, a luminescent device includes the color conversion luminescent sheet.

Namely, the luminescent device may be a device in which the color conversion luminescent sheet is integrally attached to a light source emitting UV, blue light or single-wavelength light, for example, an organic light-emitting device (OLED), an inorganic light-emitting device (LED), or a lamp.

The luminescent device, including the color conversion luminescent sheet, converts light irradiated onto the luminescent sheet from the light source into wavelengths of blue light, red light, or green light, according to the type of the color conversion luminescent material used in the sheet, while allowing some of the irradiated light to pass through it, generating white light as well as light of various colors resulting from a combination of various wavelengths and intensities.

One or more embodiments will now be described in more detail with reference to the following examples. However, these examples are for illustrative purposes only and are not intended to limit the scope of the one or more embodiments.

### Example 1

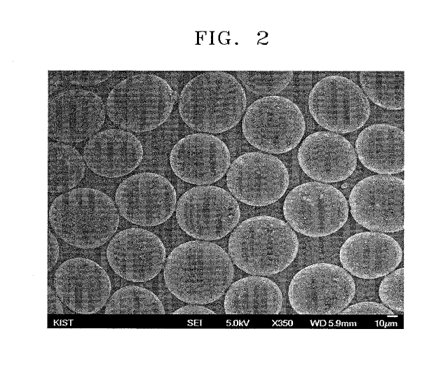

A conductive layer was formed of ITO on a rear surface of a microlens sheet (Product Name: UTE12-7B, available from MIRAE NANOTECH CO., LTD), by using a sputtering method. FIG. 2 is an image of the lens surface of the microlens sheet.

0.4 g of polymethyl methacrylate (PMMA; Mw 1,000,000, available from Aldrich Co. Ltd.) was added to a mixed solvent of 6 mL of toluene and 2 mL of dimethylformamide, and was sufficiently dissolved at room temperature to prepare a binder resin solution. 0.09 g of a 7:3 by weight mixture of green quantum dots (CeSe/ZnS) (available from Nanosquare Co., Ltd.) and red quantum dots, as a color conversion luminescent material, was added to the binder resin solution and sufficiently mixed at room temperature with a magnetic bar, and was then dispersed for 1 hour using a untrasonicator to prepare a color conversion luminescent composition. The color conversion luminescent composition was applied on the conductive layer formed on the rear surface of the optical sheet (microlens sheet) by using electrospinning to form a composite nanofiber-nanobead layer including the PMMA and the color conversion luminescent material.

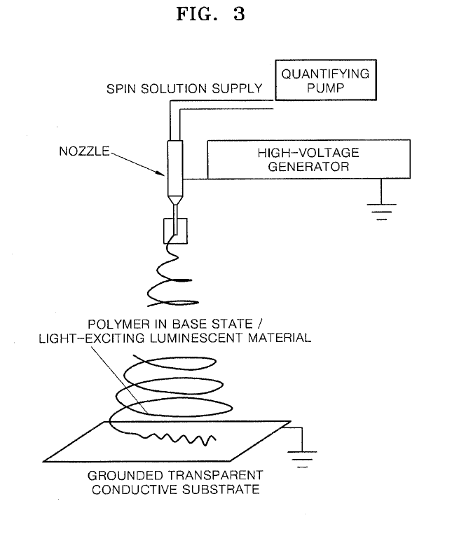

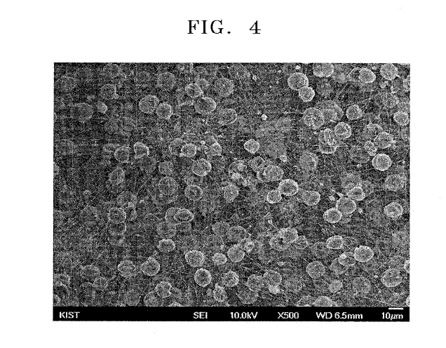

The electrospinning was carried out using an electrospinning apparatus illustrated in FIG. 3. With the conductive layer (having a size of 5 cm×5 cm) as the grounded receiver, and a metal needle attached to a pump capable of adjusting the discharge rate as the positive electrode, a voltage of about 15 kV was applied between the two electrodes. The conductive layer had an area specific resistance of about 20 Ω/sq, and a tip-to-tip distance was set at about 10 cm. The electrospinning was carried out at a discharge rate of the spin solution of 20 μL/min until a total discharge amount reached about 1,000 μL, to form on the conductive layer the composite nanofiber-nanobead layer, including the polymethylmethacrylate and the color conversion luminescent material, to have a thickness of about 3 μm, which was then pressed at about 50° C. for about 10 minutes at a pressing rate of 2 tons/100 cm² to form a color conversion luminescent layer having a thickness of about 1 μm, thereby forming a color conversion luminescent sheet. A surface of the color conversion luminescent layer was observed. The result is shown in FIG. 4.

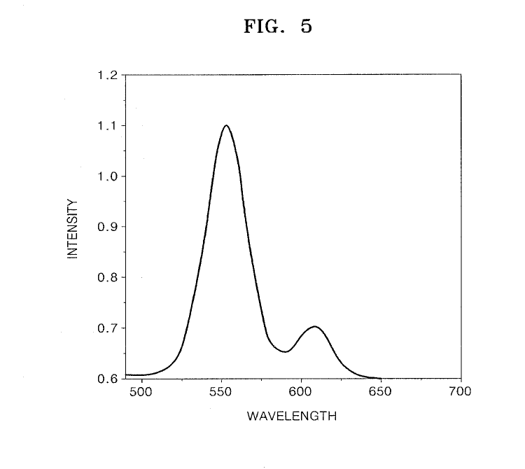

An emission spectrum of the color conversion luminescent sheet of Example 1 when excited at a wavelength of 470 nm was analyzed. The result is shown in FIG. 5. Two peaks were identified at about 550 nm and about 610 nm, respectively, and color coordinates were identified to be (0.515, 0.482).

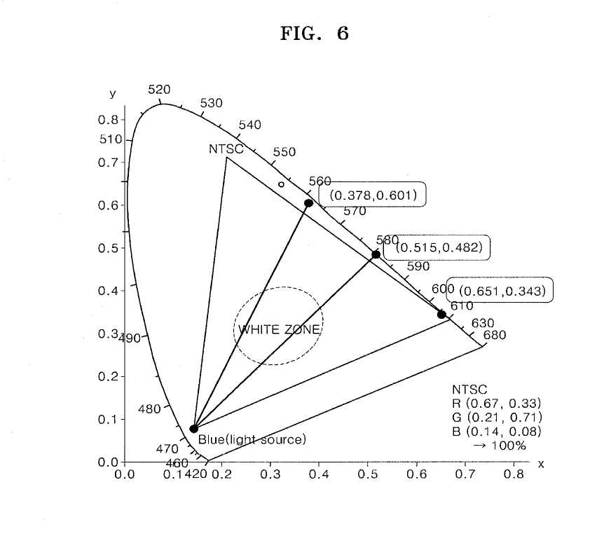

Color coordinates of when the color conversion luminescent sheet of Example 1 was used along with a blue organic light-emitting device emitting blue light of about 470 nm, are illustrated in FIG. 6. In general, the allowable range of white light for illuminators and light sources is as wide as illustrated in FIG. 6. The blue organic light-emitting device including the color conversion luminescent sheet of Example 1 may emit white light with the color coordinates (0.30, 0.34), as shown in FIG. 6.

### Comparative Example 1

A color conversion luminescent sheet was prepared in the same manner as in Example 1, except that a conductive layer was formed by sputtering a conductive material ITO onto a rear surface of a polyethyleneterephthalate (PET) film (available from SKC Co. Ltd). A microlens sheet, the same kind as used in Example 1, was attached to an upper surface of the PET film.

### Comparative Example 2

A color conversion luminescent sheet was prepared in the same manner as in Example 1, except that an ITO glass substrate (20 Ω/sq, available from Samsung Corning Precision Glass Co. Ltd.) was used.

A microlens sheet, the same kind as used in Example 1, was attached to the color conversion luminescent layer.

<Evaluation of Color Conversion Luminescent Sheet>

Luminescences of the color conversion luminescent sheets prepared in Example 1 and Comparative Examples 1 and 2 were measured using a Luminance Meter LS-110 (available from MINOLTA).

The color conversion luminescent sheet of Example 1 had a luminescence of about 800 cd/m², while the luminescence of color conversion luminescent sheet of Comparative Example 1 was about 500 cd/m² before the microlens sheet was attached, and about 630 cd/m² when the microlens sheet was attached. The luminescence of color conversion luminescent sheet of Comparative Example 2 was about 510 cd/m² before the microlens sheet was attached, and about 640 cd/m² when the microlens sheet was attached. The blue light (having a wavelength of about 470 nm) used as the base light source had a luminescence of about 300 cd/m².

Thus, from the luminescence evaluation results with respect to the color conversion sheets, the color conversion luminescent sheet of Example 1, which includes the conductive layer directly formed on the optical (microlens) sheet with surface protrusions and depressions is found to improve the light efficiency of a light source compared to the color conversion luminescent sheets of Comparative Examples 1 and 2.

As described above, according to the one or more of the above embodiments of the present invention, using a combination of color conversion luminescent materials that are able to transmit and/or absorb part UV light, blue light, and various monochromatic and convert them into a white light or a color light having at least two colors, or all three out of blue, red, and green, a color conversion luminescent sheet that ensures easy control of luminescence and color coordinates and has good reproducibility can be readily prepared. In addition, a light diffusion effect produced by an optical sheet with a plurality of protrusions and depressions, can maximize the optical efficiency of a light source. Furthermore, the presence of a protective layer formed on the upper surface of the color conversion luminescent layer of the inventive sheet may further help ensure the stability and reliability of the sheet by protecting the organic layer within the color conversion luminescent layer effectively from moisture and oxygen.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A color conversion luminescent sheet comprising:
an optical sheet having a plurality of protrusions and depressions on its lower surface;
a conductive layer disposed on the upper surface of the optical sheet; and
a color conversion luminescent layer deposited on the upper surface of the conductive layer and comprising a mixture of nanofibers and nanobeads having a binder resin and a color conversion luminescent material.

2. The color conversion luminescent sheet of claim 1, wherein each one of the protrusions and depressions has a cross-sectional shape selected from among a triangle, a polygon, a semi-circular pillar, a semi-oval pillar, a cone, and a microlens.

3. The color conversion luminescent sheet of claim 2, wherein the microlens shape has a height of from about 2 μm to about 150 μm, and a radius of curvature of from about 2 μm to about 150 μm.

4. The color conversion luminescent sheet of claim 1, wherein the optical sheet is selected from the group consisting of polyethylene terephthalate (PET), polymethyl methacrylate (PMMA), polycarbonate PC), polyethylene naphthalate (PEN), polystyrene (PS), and polyethylene sulfone (PES).

5. The color conversion luminescent sheet of claim 1, wherein the optical sheet has a thickness of from about 100 μm to about 500 μm.

6. The color conversion luminescent sheet of claim 2, wherein the conductive layer comprises at least one conductive material selected from the group consisting of indium tin oxide (ITO), F-doped SnO₂ (FTO), antimony tin oxide (ATO), indium zinc oxide (IZO), carbon nanotubes, graphene, polypyrrole, polyaniline, and polythiophene.

7. The color conversion luminescent sheet of claim 1, wherein the color conversion luminescent material is selected from the group consisting of inorganic fluorescent materials, organic fluorescent materials, organic luminescent polymers, phosphorescent materials, quantum dots, and combinations thereof.

8. The color conversion luminescent sheet of claim 1, wherein the color conversion luminescent layer has a thickness of from about 0.5 nm to about 200 nm.

9. The color conversion luminescent sheet of claim 1, further comprising a protective layer on the upper surface of the color conversion luminescent layer, the protective layer having a stacked structure including an organic polymer protective layer and an inorganic thin protective layer.

10. The color conversion luminescent sheet of claim 2, wherein the organic polymer protective layer comprises a cured product of a photocurable polymer selected from the group consisting of epoxy resins, acrylic resins, polyimides, and polyethylene.

11. The color conversion luminescent sheet of claim 9, wherein the inorganic thin protective layer comprises at least two inorganic materials selected from the group consisting of aluminum oxide, silicon oxide, silicon nitride, silicon oxynitride, magnesium oxide, indium oxide, and magnesium fluoride.

12. The color conversion luminescent sheet of claim 9, wherein the organic polymer protective layer has a thickness of from about 0.1 μm to about 10 μm, and the inorganic polymer protective layer has a thickness of from about 10 nm to about 1 μm.

13. The color conversion luminescent sheet of claim 1, further comprising a protective layer between the optical sheet and the conductive layer.

14. A method of preparing a color conversion luminescent sheet, the method comprising:
forming a conductive layer on one surface of an optical sheet having a plurality of protrusions and depressions on the other surface;
forming a mixed layer of nanofibers and nanobeads by spinning a color conversion luminescent composition prepared by mixing a binder resin, a color conversion luminescent material, and a solvent onto the upper surface of the conductive layer; and
thermally pressing the mixed layer of nanofibers and nanobeads to form a color conversion luminescent layer.

15. The method of claim 14, wherein the color conversion luminescent composition comprises a color conversion luminescent material of about 0.01 part to about 20 parts by weight, and a solvent of about 200 parts to about 10,000 parts by weight, each based on 100 parts by weight of the binder resin.

16. The method of claim 14, wherein the solvent comprises a polar solvent and a nonpolar solvent, and a weight ratio of the polar solvent to the nonpolar solvent is from about 2:98 to about 60:40.

17. The method of claim 14, wherein the conductive layer has an area specific resistance of from about 10 ohm/sq to about 2,000 ohm/sq.

18. The method of claim 14, wherein the spinning is carried out using electro-spinning, melt-blown spinning, electro-blown spinning, flash spinning, or electrostatic melt-blown spinning.

19. The method of claim 14, wherein the nanofiber has a diameter of from about 10 nm to about 10,000 nm, and the nanobead has a diameter of from about 30 nm to about 10,000 nm.

20. The method of claim 14, wherein the thermal pressing is carried out at a temperature of from about 25° C. to about 150° C.

21. The method of claim 14, further comprising a protective layer on an upper surface of the color conversion luminescent layer.

22. The method of claim 14, further comprising forming a protective layer on the surface of the optical sheet opposite to the surface of said protrusions and depressions before forming the conductive layer.

23. A luminescent device comprising the color conversion luminescent sheet of claim 1.
